(19) United States
(12) Patent Application Publication
(10) Pub. No.: US 2024/0204158 A1
(43) Pub. Date: Jun. 20, 2024

(54) WIRING SUBSTRATE, LIGHT-EMITTING DEVICE, AND MANUFACTURING METHODS THEREOF

(71) Applicant: NICHIA CORPORATION, Anan-shi (JP)

(72) Inventor: Kenji SUZUKI, Tokushima-shi (JP)

(73) Assignee: NICHIA CORPORATION, Anan-shi (JP)

(21) Appl. No.: 18/536,237

(22) Filed: Dec. 12, 2023

(30) Foreign Application Priority Data
Dec. 20, 2022 (JP) 2022-203717

(51) Int. Cl. H01L 33/62; H01L 33/60

(52) U.S. Cl. CPC H01L 33/62; H01L 33/60; H01L 2933/0066

(57) ABSTRACT

A wiring substrate including a substrate including an insulating portion with a through hole connecting a first surface and a second surface, and a metal portion faces the second surface and closes the through hole to form a blind hole. A conductor is disposed in the blind hole. The metal portion being a bottom surface defining the blind hole includes a first recess, a second recess, and a first lateral wall between the first and second recesses. In a cross-sectional view, the first lateral wall includes a first lower end portion in the first recess, a second lower end portion in the second recess, and a first top portion between the first and second lower end portions, The first top portion is immediately above a bottom surface defining the first recess, and the first lower end portion is closer to the second recess than the first top portion.

### CROSS-REFERENCE TO RELATED APPLICATIONS

The present application claims priority under 35 U.S.C. § 119 to Japanese Patent Application No. 2022-203717, filed Dec. 20, 2022, the contents of which is hereby incorporated by reference in its entirety.

### BACKGROUND

### 1. Technical Field

The present disclosure relates to a wiring substrate, a light-emitting device, and manufacturing methods of the wiring substrate and the light-emitting device.

### 2. Description of Related Art

Conventionally, a hole of a blind via to be provided in a wiring substrate is formed by laser processing. In addition, laser irradiation may be separately performed after the hole is formed, in order to remove the residue or process the bottom surface of the hole. For example, Japanese Patent Publication No. 2014-232862 describes a blind via in which ring-shaped protrusions and recessions are formed by adjusting the intensity distribution of laser irradiated to copper exposed on the bottom surface of the blind via.

### SUMMARY

Embodiments of the present disclosure provide a wiring substrate, a light-emitting device, and manufacturing methods thereof that can improve strength in a connection between a metal of a bottom surface of a blind hole (via) and a conductive paste.

According to one aspect of the present invention, a wiring substrate including a substrate including an insulating portion and a metal portion, the insulating portion having a first surface and a second surface opposite to the first surface, the insulating portion including a through hole penetrating and connecting the first surface and the second surface, the metal portion facing the second surface of the insulating portion, closing the through hole, and forming a blind hole; and a conductor disposed in the blind hole, in which a portion of the metal portion being a bottom surface defining the blind hole includes at least a first recess, a second recess, and a first lateral wall located between the first recess and the second recess, in a cross-sectional view taken along a thickness direction of a portion of the metal portion located in the blind hole, the first lateral wall includes a first lower end portion located in the first recess, a second lower end portion located in the second recess, and a first top portion located between the first lower end portion and the second lower end portion, the first top portion is located immediately above a bottom surface defining the first recess, and the first lower end portion is located closer to the second recess than the first top portion.

According to another aspect of the present invention, a light-emitting device including the wiring substrate disclosed in the embodiments; and a light-emitting element disposed on the wiring substrate, in which the light-emitting element is electrically connected to the metal portion.

According to another aspect of the present invention, a method of manufacturing a wiring substrate, the method including providing a substrate including an insulating portion and a metal portion, the insulating portion having a first surface and a second surface opposite to the first surface, the metal portion facing the second surface of the insulating portion; forming a primary blind hole by irradiating a first surface of the insulating portion with first laser light and removing at least a part of the insulating portion; forming a blind hole having a portion of the metal portion as a bottom surface by irradiating a bottom surface defining the primary blind hole with second laser light having a shorter wavelength than the first laser light; disposing a conductive paste in the blind hole; and forming a conductor by curing the conductive paste, in which, in the forming the blind hole, the second laser light is irradiated in such a manner that, in the portion of the metal portion being the bottom surface defining the blind hole, a plurality of recesses including at least a first recess and a second recess are formed, and a first lateral wall is formed between the first recess and the second recess.

According to further aspect of the present invention, a method of manufacturing a light-emitting device, the method including providing a wiring substrate by the method of manufacturing the wiring substrate according to the embodiments; disposing a light-emitting element on the wiring substrate; and electrically connecting the light-emitting element and the metal portion.

According to the embodiments of the present disclosure, it is possible to provide a wiring substrate, a light-emitting device, and manufacturing methods thereof that improve strength in the connection between a metal of a bottom surface of a blind via and a conductive paste.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1A is a schematic perspective view illustrating a part of a wiring substrate according to an embodiment on a second surface side.

FIG. 1B is a schematic perspective view illustrating a part of a wiring substrate according to an embodiment on a first surface side.

FIG. 1C is a schematic plan view illustrating a part of a wiring substrate according to an embodiment on a second surface side.

FIG. 1D is a schematic plan view illustrating a part of a wiring substrate according to an embodiment on a first surface side.

FIG. 2A is a schematic plan view illustrating a via connecting portion according to an embodiment on a first surface side.

FIG. 2B is a schematic plan view illustrating a blind hole and a stepped portion according to an embodiment with a conductor omitted.

FIG. 2C is a schematic cross-sectional view taken along the line IIC-IIC in FIG. 2A.

FIG. 2D is a schematic cross-sectional view taken along the line IID-IID in FIG. 2B.

FIG. 3 is a flowchart illustrating a method of manufacturing a wiring substrate according to an embodiment.

FIG. 4A is a schematic cross-sectional view illustrating a substrate provided in a method of manufacturing a wiring substrate according to an embodiment.

FIG. 4B is a schematic cross-sectional view illustrating a state in which a wiring pattern of a metal portion has been formed in a method of manufacturing a wiring substrate according to an embodiment.

FIG. 4C is a schematic cross-sectional view illustrating a state in which a primary blind hole has been formed in a method of manufacturing a wiring substrate according to an embodiment.

FIG. 4D is a schematic cross-sectional view illustrating a state in which a blind hole including a plurality of recesses on a bottom surface has been formed in a method of manufacturing a wiring substrate according to an embodiment.

FIG. 4E is a schematic cross-sectional view illustrating a state in which a conductive paste has been disposed in a method of manufacturing a wiring substrate according to an embodiment.

FIG. 4F is a schematic cross-sectional view illustrating a state in which a conductor has been formed in a method of manufacturing a wiring substrate according to an embodiment.

FIG. 5A is a schematic plan view illustrating irradiation of second laser light in a method of manufacturing a wiring substrate according to an embodiment.

FIG. 5B is a schematic cross-sectional view illustrating a state in which a first recess has been formed in a method of manufacturing a wiring substrate according to an embodiment.

FIG. 5C is a schematic cross-sectional view illustrating a state in which the first recess and a second recess have been formed in a method of manufacturing a wiring substrate according to an embodiment.

FIG. 5D is a photograph illustrating a blind hole formed in a method of manufacturing a wiring substrate according to an embodiment.

FIG. 6 is a schematic plan view illustrating a part of a mask that is used to dispose a conductive paste in a method of manufacturing a wiring substrate according to an embodiment.

FIG. 7A is a schematic plan view illustrating a light-emitting device according to an embodiment.

FIG. 7B is a schematic plan view illustrating a part of a wiring substrate in a light-emitting device according to an embodiment.

FIG. 7C is a schematic cross-sectional view taken along the line VIIC-VIIC in FIG. 7A illustrating a light-emitting device according to an embodiment.

FIG. 8 is a flowchart illustrating a method of manufacturing a light-emitting device according to an embodiment.

FIG. 9A is a schematic cross-sectional view illustrating a wiring substrate provided in a method of manufacturing a light-emitting device according to an embodiment.

FIG. 9B is a schematic cross-sectional view illustrating a state in which light-emitting elements have been disposed in a method of manufacturing a light-emitting device according to an embodiment.

FIG. 9C is a schematic cross-sectional view illustrating a state in which a light-reflecting member has been disposed in a method of manufacturing a light-emitting device according to an embodiment.

FIG. 9D is a schematic cross-sectional view illustrating a state in which a first light guide member has been disposed in a method of manufacturing a light-emitting device according to an embodiment.

FIG. 9E is a schematic cross-sectional view illustrating a state in which a second light guide member has been disposed in a method of manufacturing a light-emitting device according to an embodiment.

FIG. 9F is a schematic cross-sectional view illustrating a state in which a light adjustment member has been disposed in a method of manufacturing a light-emitting device according to an embodiment.

### DETAILED DESCRIPTION OF EMBODIMENT

### Description of Embodiments

Embodiments according to the present disclosure will be described below with reference to the drawings. However, the embodiments described below are merely intended to embody the technical concept according to the present disclosure, and the invention is not limited to the following description unless otherwise specified. The content described in one embodiment can also be applied to another embodiment or modified example. The drawings are diagrams that schematically illustrate the embodiments. In order to provide clarity in the description, scales, intervals, positional relationships, and the like of members may be exaggerated, some of the members may be omitted in the drawings, or an end surface view that only illustrates a cut section may be used as a cross-sectional view. Directions illustrated in the drawings indicate relative positions between constitution components and are not intended to indicate absolute positions. Members having the same names and reference characters represent, as a rule, the same members or members of the same quality, and detailed description thereof is omitted as appropriate. In the embodiments, “covering” includes not only a case of covering by direct contact but also a case of indirectly covering, for example, via another member.

### Wiring Substrate

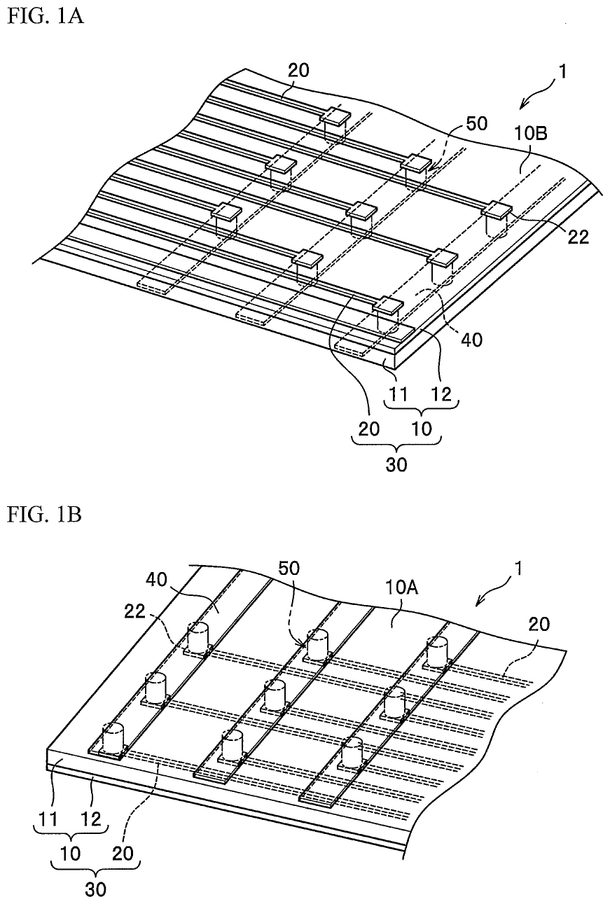

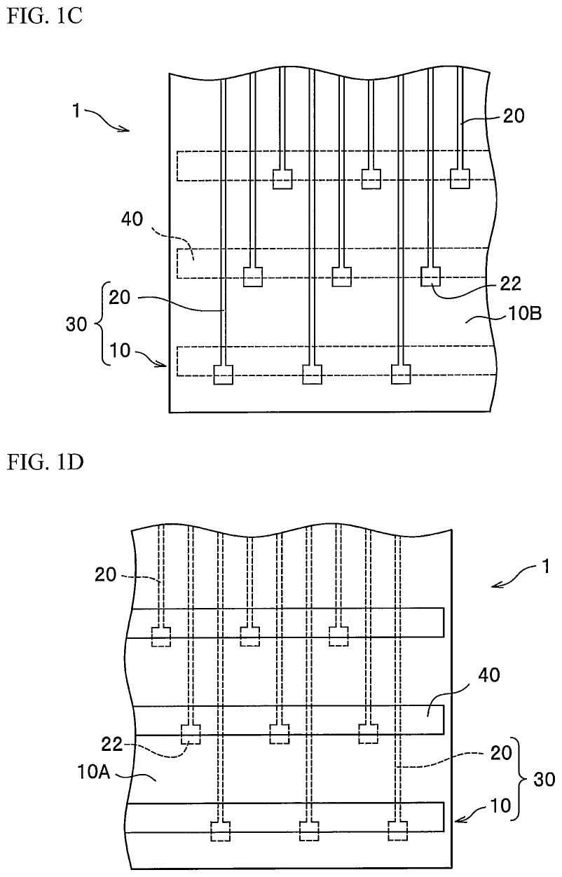

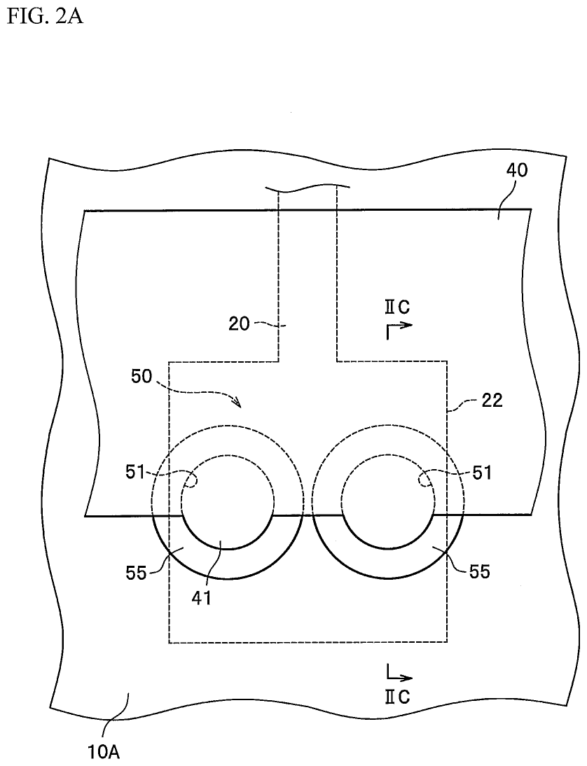

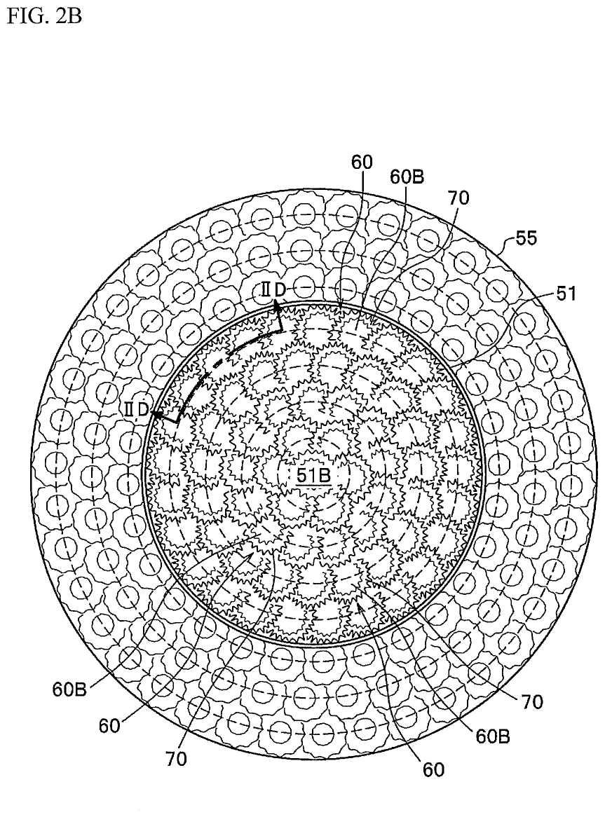

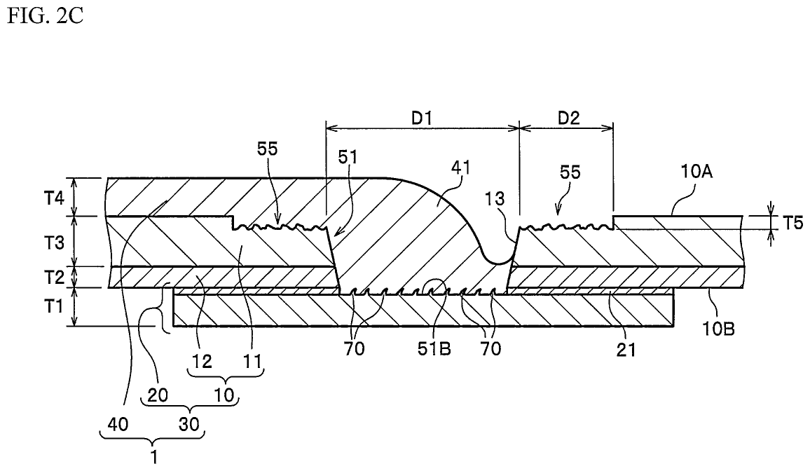

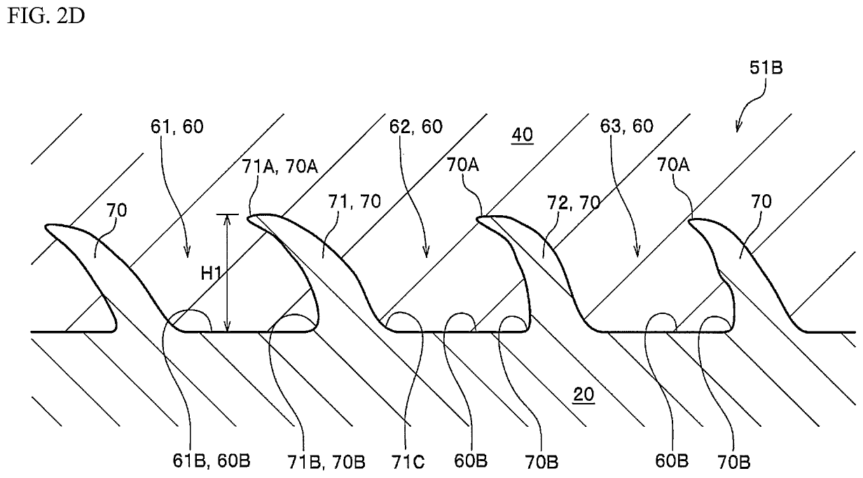

A wiring substrate 1 according to an embodiment will be described with reference to FIGS. 1A to 2D. FIG. 1A is a schematic perspective view illustrating a part of the wiring substrate 1 on a second surface 10B side. FIG. 1B is a schematic perspective view illustrating a part of the wiring substrate 1 on a first surface 10A side. FIG. 1C is a schematic plan view illustrating a part of the wiring substrate 1 on the second surface 10B side. FIG. 1D is a schematic plan view illustrating a part of the wiring substrate 1 on the first surface 10A side. FIG. 2A is a schematic plan view illustrating a via connecting portion 50 on the first surface 10A side. FIG. 2B is a schematic plan view illustrating a blind hole 51 and a stepped portion 55 with a conductor 40 omitted. FIG. 2C is a schematic cross-sectional view taken along the line IIC-IIC in FIG. 2A. FIG. 2D is a schematic cross-sectional view taken along the line IID-IID in FIG. 2B. The conductor 40 disposed on a part of the stepped portion 55 and in the blind hole 51 is not illustrated in FIG. 2B but is illustrated in FIG. 2D.

As illustrated in FIGS. 1A to 1D, the wiring substrate 1 can be provided with electrical wires of mutually different patterns on both surfaces. The wires on both surfaces are connected by via connecting portions 50. A wire by a metal portion 20 to be described below is provided on one surface of the wiring substrate 1, and a wire by a conductor 40 to be described below is provided on the opposite surface. The via connecting portion 50 includes a blind hole 51 to be described below and connects wires on both surfaces by the conductor 40. An example of the via connecting portion 50 is illustrated in an enlarged manner in FIG. 2A.

The wiring substrate 1 includes a substrate 30 including an insulating portion 10, which has a first surface 10A and a second surface 10A opposite to the first surface 10B and includes a through hole 13 penetrating and connecting the first surface 10A and the second surface 10B, and a metal portion 20, which faces the second surface 10B of the insulating portion 10, closes the through hole 13, and forms a blind hole 51, and a conductor 40 disposed in the blind hole 51. A portion of the metal portion 20 being a bottom surface 51B defining the blind hole 51 includes at least a first recess 61, a second recess 62, and a first lateral wall 71 located between the first recess 61 and the second recess 62. In a cross-sectional view taken along the thickness direction of a portion of the metal portion 20 located in the blind hole 51, the first lateral wall 71 includes a first lower end portion 71B located in the first recess 61, a second lower end portion 71C located in the second recess 62, and a first top portion 71A located between the first lower end portion 71B and the second lower end portion 71C. The first top portion 71A is located immediately above the bottom surface 61B defining the first recess 61, and the first lower end portion 71B is located closer to the second recess 62 than the first top portion 71A. Components of the wiring substrate 1 will be described below.

### Substrate

The substrate 30 is a plate-like or sheet-like member serving as a base of the wiring substrate 1. The shape of the substrate 30 in a plan view is rectangular, for example. However, the shape of the substrate 30 in a plan view is not specifically limited. The substrate 30 includes the insulating portion 10 and the metal portion 20 that serves as a wire and faces the second surface 10B of the insulating portion 10. The conductor 40 serving as a wire is disposed on the first surface 10A of the insulating portion 10. The wire of the metal portion 20 and the wire of the conductor 40 are connected to each other through the via connecting portion 50 (through hole and conductor) serving as a wire formed by penetrating the insulating portion 10.

### Insulating Portion

The insulating portion 10 is a plate-like or sheet-like insulating member serving as a base on which a wiring pattern is formed. The insulating portion 10 has a first surface 10A and a second surface 10B opposite to the first surface 10A and is formed with a blind hole 51 that is a through hole penetrating so as to connect the first surface 10A and the second surface 10B. Here, the insulating portion 10 includes two layers of a polyimide layer 11 and a resin layer 12, the polyimide layer 11 side is the first surface 10A, and the resin layer 12 side is the second surface 10B. A thickness T3 of the polyimide layer 11 is in a range from 12 μm to 75 μm, for example, and a thickness T2 of the resin layer 12 is in a range from 5 μm to 20 μm, for example. The material, structure, and thickness of the insulating portion 10 are not specifically limited.

### Metal Portion

The metal portion 20 is a conductive member that forms a wiring pattern set in advance. Examples of the material of the metal portion 20 include a single-component metal such as Ag, Al, Ni, Au, Cu, Ti, Pt, and W, and an alloy containing these metals. Here, a copper plate is used as an example of the metal portion 20. A thickness T1 of the copper plate is in a range from 12 μm to 35 μm, for example. The wiring pattern of the metal portion 20 can be formed by etching.

The metal portion 20 can be provided with a connection pad portion 22. The connection pad portion 22 is a part of the metal portion 20 formed to have a large width, for example, so that the via connecting portion 50 can be easily provided. Here, the connection pad portion 22 having a rectangular shape is provided at the tip end portion of the wiring pattern of the metal portion 20 and is disposed so as to have a region overlapping the wire by the conductor 40, to be described below, in a plan view. The connection pad portion 22 can be formed by etching together with the wiring pattern.

The surface of the metal portion 20 is preferably subjected to an anti-rust treatment. In particular, an anti-rust layer 21 is preferably formed on the surface of the metal portion 20 facing the insulating portion 10. The anti-rust layer 21 includes a roughened layer obtained by performing roughening treatment by forming protrusions and recessions on the surface, a plating layer of Zn, Ni, Cr, or the like, or an organic film layer, for example, and forms a surface of a copper plate or the like as the metal portion 20. The anti-rust layer 21 suppresses oxidation of the metal portion 20 such as a copper plate and enhances adhesion to the insulating portion 10. However, the electrical resistance of the anti-rust layer 21 is larger than that of a copper plate or the like. Therefore, when an electrical contact is to be provided on the surface of the copper plate or the like facing the insulating portion 10, the anti-rust layer 21 is preferably removed in order to reduce the electrical resistance at the electrical contact. The anti-rust layer 21 can be removed by irradiation with laser light to evaporate the anti-rust layer 21, chemical reaction with a reducing agent, mechanical grinding, or the like, for example. The thickness of the anti-rust layer 21 is in a range from 0.1 μm to 7 μm, for example.

### Conductor

The conductor 40 is a member that forms a wire disposed on the first surface 10A and connects the wire disposed on the first surface 10A and the metal portion 20 facing the second surface 10B. The conductor 40 is disposed on the first surface 10A as a wire and is disposed in the blind hole 51 to be described below.

While the volume resistivity of the copper plate is 1.7 μΩ·cm, for example, the volume resistivity of the conductor 40 is in a range from 10 μΩ·cm to 100 μΩ·cm, for example. In order to reduce the wire resistance of the conductor 40, the cross-sectional area of the wire can be increased. A wiring thickness T4 of the conductor 40 related to the wire disposed on the first surface 10A is set to a range from 10 μm to 30 μm, for example, in order to make the wiring substrate 1 as thin as possible. Therefore, the wiring width of the conductor 40 is preferably in a range from 0.5 mm to 2 mm.

Examples of the material of the conductor 40 include a simple substance such as gold, silver, copper, platinum, and aluminum, an alloy thereof, and a mixture of a mixed powder thereof and a resin binder. Examples of the resin binder include a thermosetting resin such as an epoxy resin and a silicone resin. The conductor 40 preferably contains a reducing agent such as an organic acid. This makes it possible to reduce the electrical resistance in the connection with the metal portion 20.

### Blind Hole

The blind hole 51 is formed by penetrating the insulating portion 10 so as to connect the first surface 10A and the second surface 10B as the through hole 13 and closing the through hole 13 with the metal portion 20 as the blind hole 51. The blind hole 51 is provided at a position facing the metal portion 20, and the surface of a portion of the metal portion 20 disposed to face the second surface 10B of the insulating portion 10 serves as a bottom surface 51B defining the blind hole 51. Here, two blind holes 51 are provided at a position facing one connection pad portion 22.

An inside diameter D1 of the blind hole 51 increases from the second surface 10B toward the first surface 10A. The maximum diameter of the blind hole 51 is preferably in a range from 100 μm to 500 μm. In addition, here, the metal portion 20 is a copper plate and includes the anti-rust layer 21 on the surface facing the second surface 10B of the insulating portion 10. The anti-rust layer 21 of a portion of the metal portion 20 being the bottom surface 51B defining the blind hole 51 has been removed.

In the wiring substrate 1, the substrate 30 includes a plurality of blind holes 51 arranged in parallel each having the surface of a portion of the continuous metal portion 20 on the insulating portion 10 side as the bottom surface 51B, and portions of the conductors 40 in contact with the corresponding bottom surfaces 51B of the plurality of blind holes 51 arranged in parallel are continuous via wires formed by a portion of the conductor 40 disposed on the first surface 10A of the insulating portion 10.

Here, as illustrated in FIG. 2A, two blind holes 51 arranged in parallel are provided for one connection pad portion 22 formed by the continuous metal portion 20. That is, in the two blind holes 51, portions of the metal portion 20 being the bottom surfaces 51B are continuous. The conductor 40 continuous in the wire on the first surface 10A covers each bottom surface 51B.

In addition, in the conductor 40, a filling portion 41 is formed so as to be continuous with the conductor 40 and enter the blind holes 51 such that the filling portion 41 protrudes from a certain width in a plan view.

### Recess

The portion of the metal portion 20 being the bottom surface 51B defining the blind hole 51 includes a plurality of recesses 60. A lateral wall 70 is provided between adjacent recesses 60. Each recess 60 is defined by a bottom surface 60B and lateral walls 70.

The plurality of recesses 60 include at least a first recess 61 and a second recess 62, and a first lateral wall 71 is provided between the first recess 61 and the second recess 62.

In a cross-sectional view taken along the thickness direction of a portion of the metal portion 20 located in the blind hole 51, the first lateral wall 71 includes a first lower end portion 71B in the first recess 61, a second lower end portion 71C in the second recess 62, and a first top portion 71A between the first lower end portion 71B and the second lower end portion 71C. The first top portion 71A is located immediately above the bottom surface 61B defining the first recess 61, and the first lower end portion 71B is located closer to the second recess 62 than the first top portion 71A.

In FIGS. 2B and 2C, the recesses 60 are disposed so as to be adjacent to each other on the entire bottom surface 51B defining the blind hole 51, and the plurality of recesses 60 are denoted by formal numbers such as “first”, “second”, and “third” for easy description.

Here, the bottom surface 51B defining the blind hole 51 has a circular shape in a plan view. The portion of the metal portion 20 being the bottom surface 51B defining the blind hole 51 includes a third recess 63 adjacent to the second recess 62 opposite to the first recess 61 and a second lateral wall 72 between the second recess 62 and the third recess 63. The first recess 61, the second recess 62, and the third recess 63 are disposed in an arc shape along the outer periphery of the bottom surface 51B defining the circular blind hole 51. That is, the plurality of recesses 60 can be concentrically disposed along the outer periphery of the blind hole 51. As will be described below, the plurality of recesses 60 are formed from the outer side toward the inner side so as to be disposed one round from the outer peripheral side of the blind hole 51, then disposed one round inside thereof, and further disposed one round inside thereof. By repeating this, a plurality of recesses 60 are spirally or concentrically disposed. The center of the concentric circles preferably coincides with the center of the bottom surface 51B defining the blind hole 51 but may not coincide with the center of the bottom surface 51B.

In a cross-sectional view taken along the thickness direction of the portion of the metal portion 20 located in the blind hole 51, the first lateral wall 71 includes a first lower end portion 71B in the first recess 61, a second lower end portion 71C in the second recess 62, and a first top portion 71A between the first lower end portion 71B and the second lower end portion 71C. A height H1 from the bottom surface 61B defining the first recess 61 to the first top portion 71A is in a range from 0.5 μm to 10 μm, for example, and preferably in a range from 1 μm to 3 μm.

The first lateral wall 71 is inclined toward the first recess 61 and overlaps a part of the bottom surface 61B defining the first recess 61 in the height direction. That is, the first top portion 71A is located immediately above the bottom surface 61B defining the first recess 61, and the first lower end portion 71B is located closer to the second recess 62 than the first top portion 71A. The conductor 40 fully fills at least the first recess 61 and the second recess 62 and enters the first lower end portion 71B.

Preferably, the lateral walls 70 are inclined so as to overlap the bottom surface 60B of one of the two adjacent recesses 60 in the height direction, and one lower end portion 70B of the lateral walls 70 is located closer to the other of the two adjacent recesses 60 than the top portion 70A. In addition, preferably, the conductor 40 fully fills the recesses 60 and enters the lower end portions 70B.

The bottom surface 60B defining the recess 60 is partially covered by the inclined lateral wall 70. Therefore, in a plan view, the area of the bottom surface 60B is the total of an area of a portion covered with the lateral wall 70 and an area of a portion not covered with the lateral wall 70. The mode value of the area of the bottom surface 60B not covered with the lateral wall 70 in a plan view is in a range from 10 μm² to 50 μm², for example, and preferably in a range from 20 μm² to 40 μm². As an example, when the area of the bottom surface 51B defining the blind hole 51 is 32000 μm², the total area of the bottom surface 60B not covered with the lateral wall 70 in a plan view can be set to a range from 5000 μm² to 20000 μm².

### Stepped Portion

The first surface 10A of a portion of the insulating portion 10 around the blind hole 51 includes a stepped portion 55 from which a part of the surface is removed so as to surround the blind hole 51. The stepped portion 55 has a substantially constant width D2 along the outer periphery of the blind hole 51 in a plan view. The width D2 of the stepped portion 55 is in a range from 1 μm to 400 μm, for example, and preferably in a range from 20 μm to 200 μm.

A height T5 of the step of the stepped portion 55 is in a range from 0.1 m to 10 μm, for example, and preferably in a range from 0.5 μm to 5 μm. The surface of the stepped portion 55 has protrusions and recessions. The height T5 of the stepped portion 55 can be a height of the first surface 10A of the insulating portion 10 from an average position of the protrusions and recessions of the stepped portion 55.

With the configuration described above, the conductor 40 enters the first lower end portion 71B of the bottom surface 51B defining the blind hole 51, which makes it possible to improve the bonding strength between the metal portion 20 and the conductor 40 and to reduce the resistance value.

The shape of the bottom surface 51B defining the blind hole 51 is not limited to the circular shape described above but can be an elliptical shape or a polygonal shape such as a triangular shape, a quadrangular shape, a pentagonal shape, or a hexagonal shape. Even when the shape of the bottom surface 51B defining the blind hole 51 is not a circular shape, the portion of the metal portion 20 being the bottom surface 51B defining the blind hole 51 can include the plurality of recesses 60 including the first recess 61 and the second recess 62. Similarly to a case in which the plurality of recesses 60 are disposed on the bottom surface 51B defining the circular blind hole 51, the plurality of recesses 60 can be disposed in a spiral shape or a concentric similar shape by repeatedly disposing the plurality of recesses 60 one round along the outer periphery of the bottom surface 51B defining the blind hole 51 and then disposing the plurality of recesses 60 one round inside thereof.

In addition, the shape of the connection pad portion 22 in a plan view can be a rectangular shape, a trapezoidal shape, or a shape including a curved portion. Instead of providing the connection pad portion 22, the blind hole 51 can be provided such that the bottom surface 51B is positioned at a part of the wiring pattern of the metal portion 20.

Furthermore, the number of blind holes 51 provided for one connection pad portion 22 or the wiring pattern of the continuous metal portion 20 can be one or can be three or more. In a case in which a plurality of blind holes 51 are provided, the blind holes 51 can be arranged in the same direction as the wire of the conductor 40 as illustrated in FIG. 2A or can be arranged in a direction different from the wire of the conductor 40.

In addition, in the portion of the metal portion 20 being the bottom surface 51B defining the blind hole 51, the region from which the anti-rust layer 21 has been removed can be a part of the bottom surface 51B defining the blind hole 51. The region from which the anti-rust layer 21 has been removed can be provided at the center of the bottom surface 51B, for example. In addition, the area in which the anti-rust layer 21 has been removed can be 20% or more, preferably 40% or more, more preferably 55% or more, and still more preferably 70% or more relative to the area of the bottom surface 51B defining the blind hole 51. The area in which the anti-rust layer 21 has been removed is preferably 80% or less relative to the area of the bottom surface 51B defining the blind hole 51. The area in which the anti-rust layer 21 has been removed can be 100% relative to the area of the bottom surface 51B defining the blind hole 51. Thus, the electrical resistance between the conductor 40 and the metal portion 20 can be reduced. In addition, there can be a plurality of regions, rather than only one region, in the blind hole 51 from which the anti-rust layer 21 has been removed. When the region from which the anti-rust layer 21 has been removed is a part of the bottom surface 51B, the recesses 60 can be disposed in the region from which the anti-rust layer 21 has been removed.

### Manufacturing Method of Wiring Substrate

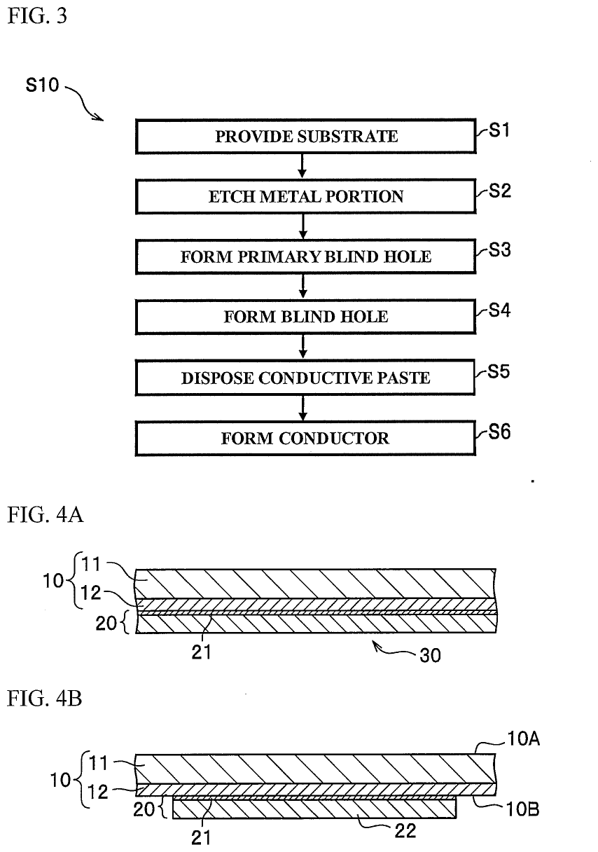

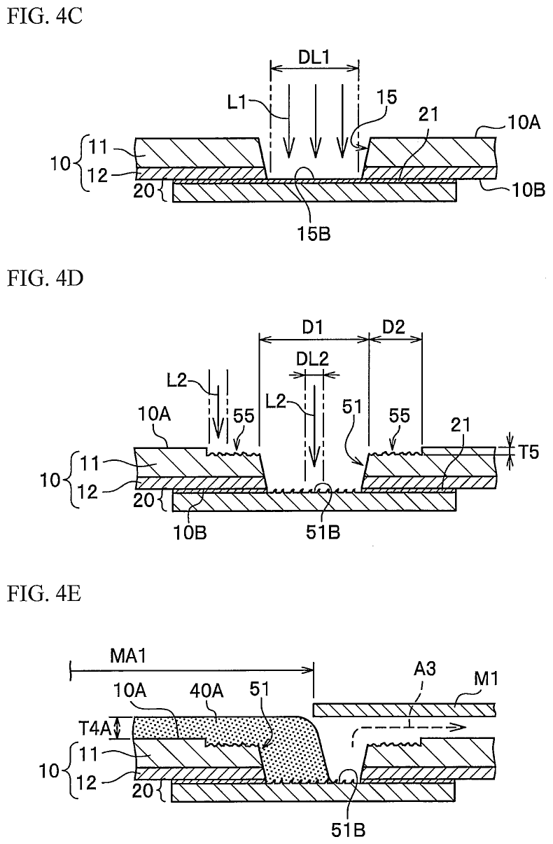

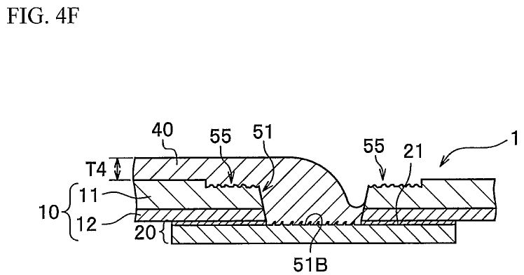

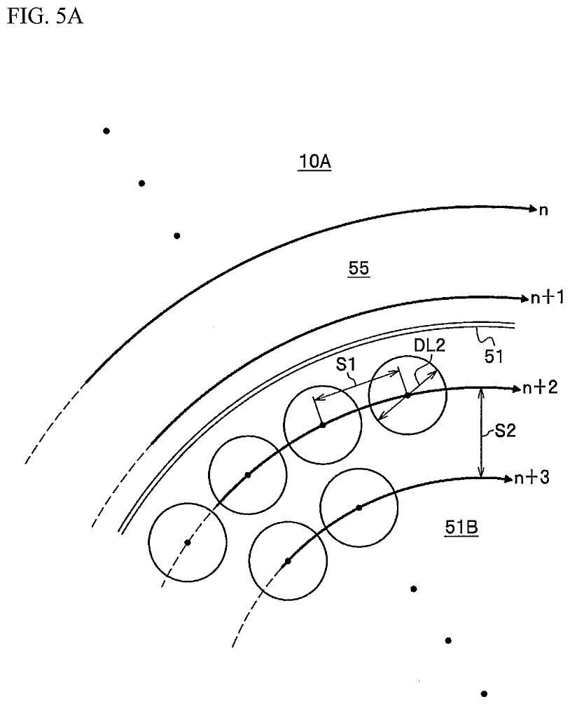

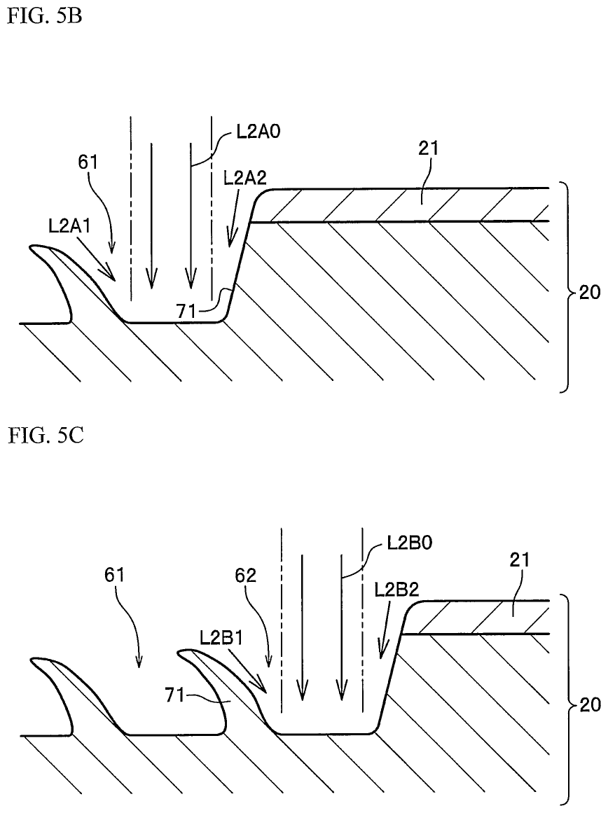

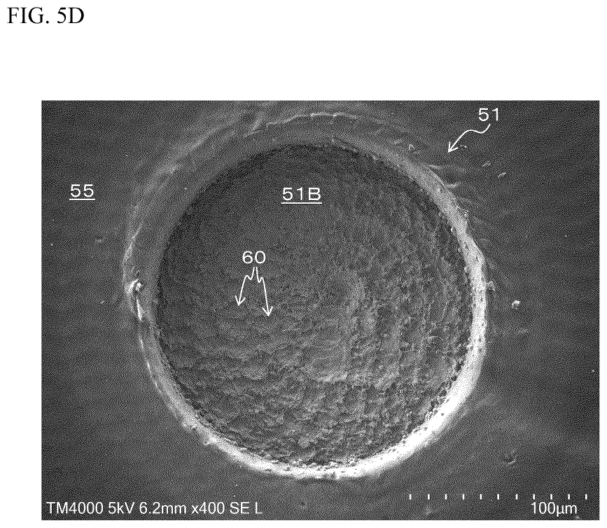

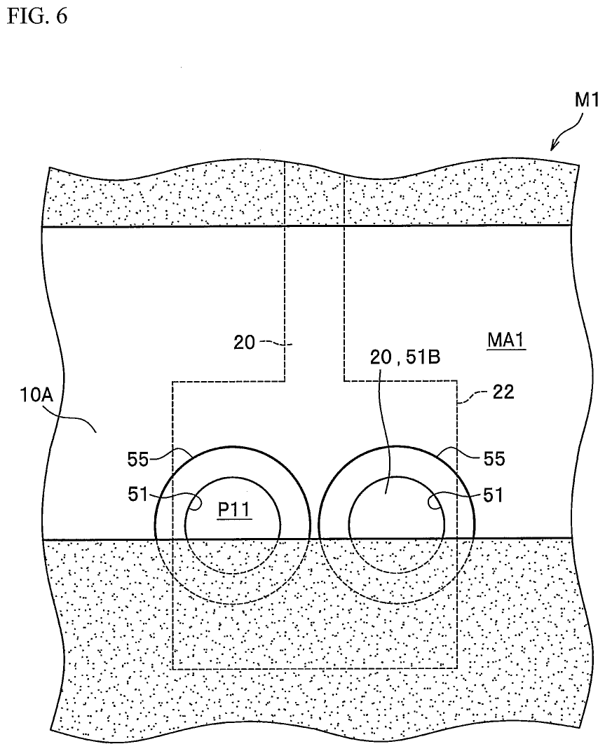

A method S10 of manufacturing a wiring substrate according to an embodiment will be described with reference to FIGS. 3 to 6. FIG. 3 is a flowchart illustrating the method S10 of manufacturing a wiring substrate. FIG. 4A is a schematic cross-sectional view illustrating a provided substrate 30. FIG. 4B is a schematic cross-sectional view illustrating a state in which a wiring pattern of a metal portion 20 has been formed. FIG. 4C is a schematic cross-sectional view illustrating a state in which a primary blind hole 15 has been formed. FIG. 4D is a schematic cross-sectional view illustrating a state in which a blind hole 51 including a plurality of recesses 60 on a bottom surface 51B has been formed. FIG. 4E is a schematic cross-sectional view illustrating a state in which a conductive paste 40A has been disposed. FIG. 4F is a schematic cross-sectional view illustrating a state in which a conductor 40 has been formed. FIG. 5A is a schematic plan view illustrating irradiation of second laser light L2. FIG. 5B is a schematic cross-sectional view illustrating a state in which a first recess 61 has been formed. FIG. 5C is a schematic cross-sectional view illustrating a state in which the first recess 61 and a second recess 62 have been formed. FIG. 5D is a photograph illustrating the formed blind hole 51. FIG. 6 is a schematic plan view illustrating a part of a mask M1 that is used to dispose the conductive paste 40A.

The method S10 of manufacturing a wiring substrate includes providing S1 a substrate 30 including an insulating portion 10, which has a first surface 10A and a second surface 10B opposite to the first surface 10A, and a metal portion 20, which faces the second surface 10B of the insulating portion 10; forming S3 a primary blind hole 15 by irradiating a first surface 10A of the insulating portion 10 with first laser light L1 and removing at least a part of the insulating portion 10; forming S4 a blind hole 51 having a portion of the metal portion 20 as a bottom surface by irradiating a bottom surface 15B defining the primary blind hole 15 with second laser light L2 having a shorter wavelength than the first laser light L1; disposing S5 a conductive paste 40A in the blind hole 51; and forming S6 a conductor 40 by curing the conductive paste 40A. In the forming S4 of the blind hole, the second laser light L2 is irradiated such that a plurality of recesses 60 including at least a first recess 61 and a second recess 62 are formed in a portion of the metal portion 20 being a bottom surface 51B defining the blind hole 51 and a first lateral wall 71 is formed between the first recess 61 and the second recess 62. Here, the etching S2 the metal portion 20 of the provided substrate 30 is performed before the forming S3 of a primary blind hole.

### Providing Substrate

In the providing S1 of the substrate, a substrate 30 in which a metal portion 20 faces one surface (second surface 10B) of an insulating portion 10 is provided. Here, an anti-rust layer 21 is provided on a surface of the metal portion 20 facing the second surface 10B of the insulating portion 10. The metal portion 20 is a copper plate, for example.

The metal portion 20 is bonded to a polyimide layer 11 serving as a base body of the insulating portion 10 via a resin layer 12 serving as an adhesive layer. The metal portion 20 and the insulating portion 10 are in a sheet shape and provided by being bonded to each other. The material, structure, and thickness of the insulating portion 10 are not specifically limited. For example, the metal portion 20 and the polyimide layer 11 can be bonded to each other by thermocompression bonding or the like without providing the resin layer 12. The substrate 30 can be provided by purchase. In addition, a material in which the insulating portion 10 is integrated by forming the polyimide layer 11 and the resin layer 12 with a polyimide resin can be used.

### Etching Metal Portion

In the etching S2 of a metal portion, the metal portion 20 is etched to form a wiring pattern. The formation of a wiring pattern includes the formation of a connection pad portion 22. A substrate on which a wiring pattern of the metal portion 20 has already been formed can be purchased in the providing S1 of a substrate. In this case, it is possible to omit the etching S2 of a metal portion.

### Forming Primary Blind Hole

In the forming S3 of a primary blind hole, a primary blind hole 15 is formed in the insulating portion 10 so as to penetrate the insulating portion 10.

Here, the primary blind hole 15 is formed in the resin-made insulating portion 10 by irradiating the first surface 10A with the first laser light L1. The laser to be used is preferably a CO₂ laser from the viewpoint of processing speed, but a green laser, a UV laser, or the like can also be used. The wavelength of the first laser light L1 is preferably in a range from 9.3 μm to 10.6 μm. The bottom surface 15B defining the primary blind hole 15 can be formed with a diameter approximately equal to a beam diameter DL1 of the first laser light L1.

### Forming Blind Hole

In the forming S4 of the blind hole, the second laser light L2 is irradiated such that, in a portion of the metal portion 20 being a bottom surface 51B defining the blind hole 51, a plurality of recesses 60 including at least a first recess 61 and a second recess 62 are formed, and a first lateral wall 71 is formed between the first recess 61 and the second recess 62. In the forming S4 of a blind hole, the blind hole 51 having the portion of the metal portion 20 as the bottom surface 51B is formed by irradiating the bottom surface defining the primary blind hole 15 with the second laser light L2 having a shorter wavelength than the first laser light L1. The second laser light L2 can have a wavelength in a range from 355 nm to 532 nm.

A portion of the metal portion 20 being the bottom surface 15B defining the primary blind hole 15 includes an anti-rust layer 21. The anti-rust layer 21 is preferably removed before the conductor 40 is disposed in the blind hole 51. The anti-rust layer 21 can be removed by irradiation of the second laser light L2 on the surface of the portion of the metal portion 20 being the bottom surface 51B defining the blind hole 51.

In addition, in the primary blind hole 15, a residue of a resin that is the material of the insulating portion 10, burrs at the peripheral edge of an opening portion, and the like are generated along with the formation of the primary blind hole 15. Similarly to the anti-rust layer 21, these are preferably removed before the conductor 40 is disposed in the blind hole 51 and can be removed by evaporation or the like by irradiation of the second laser light L2.

The second laser light L2 is irradiated so as to form a plurality of recesses 60 in the portion of the metal portion 20 being the bottom surface 51B defining the blind hole 51. The second laser light L2 is irradiated such that the recesses 60 include at least a first recess 61 and a second recess 62 and a first lateral wall 71 is formed between the first recess 61 and the second recess 62. Accordingly, it is possible to improve the bonding strength between the metal portion 20 and the conductor 40 in the blind hole 51 and to reduce the resistance value.

The second laser light L2 is irradiated such that, in a cross-sectional view taken along the thickness direction of a portion of the metal portion 20 located in the blind hole 51, the first lateral wall 71 includes a first lower end portion 71B in the first recess 61, a second lower end portion 71C in the second recess 62, and a first top portion 71A between the first lower end portion 71B and the second lower end portion 71C. Irradiation is preferably performed such that the first top portion 71A is located immediately above the bottom surface 61B defining the first recess 61 and the first lower end portion 71B is located closer to the second recess 62 than the first top portion 71A. Accordingly, the bonding strength between the metal portion 20 and the conductor 40 can be further improved.

In the irradiation of the second laser light L2, pulsed laser light can be used. It is possible to suppress deformation or the like due to heat by adjusting the length of time of one irradiation of the pulsed laser light, that is, the pulse width of the pulsed laser light. The pulse width of the second laser light L2 can be set to a range from 5 ns to 50 ns, for example. Here, the irradiation position is moved for each irradiation, i.e., for each shot. One recess 60 is formed by one shot of the second laser light L2. Accordingly, the recesses 60 can be formed efficiently.

The bottom surface 60B defining the recess 60 can be formed with a diameter approximately equal to a beam diameter DL2 of the second laser light L2. In addition, the thicknesses of the lateral wall 70 can be adjusted by an interval S1 between the shot irradiation positions. The interval S1 between the irradiation positions is the interval between the centers of adjacent beams. As an example, on the bottom surface 51B defining the blind hole 51, the beam diameter DL2 can be set to a range from 10 μm to 50 μm, and the interval S1 between the irradiation positions of consecutive shots can be set to a range from 5 μm to 50 μm.

When the portion of the metal portion 20 being the bottom surface 51B defining the blind hole 51 is irradiated with the second laser light L2, the metal portion 20 is irradiated with first emission light which is light of one shot of the second laser light L2. The first emission light is irradiated to the metal portion 20 as direct irradiation light L2A0 and irradiation light L2A1 and L2A2 via the insulating portion 10 after being reflected or the like by the insulating portion 10. The first recess 61 and the first lateral wall 71 are formed by the first emission light. Second emission light which is light of the next shot of the second laser light L2 moves the irradiation position by the interval S1 and is irradiated to the metal portion 20 near the first recess 61 so as to partially overlap the first lateral wall 71. Similarly to the first emission light, the second emission light is irradiated to the metal portion 20 as direct irradiation light L2B0 and irradiation light L2B1 and L2B2 via the insulating portion 10 after being reflected or the like by the insulating portion 10. The second recess 62 is formed and the first lateral wall 71 is deformed so as to be inclined toward the first recess 61 by the second emission light. Accordingly, the first recess 61 can be formed so as to include a region in which the first lateral wall 71 covers the bottom surface 61B like eaves.

The irradiation of the second laser light L2 is performed on a region including the blind hole 51 and larger than the blind hole 51 in a plan view. Accordingly, the stepped portion 55 in which a part of the insulating portion 10 has been removed by irradiating the first surface 10A of the insulating portion 10 around the blind hole 51 with the second laser light L2 can be formed.

The second laser light L2 is irradiated so as to fill the region to be irradiated while moving the irradiation position. Preferably, the irradiation of the second laser light L2 is started from the outer side apart from the blind hole 51, the irradiation is performed so as to circle around the blind hole 51 while gradually reducing the diameter of the circle, and the irradiation is finished inside the blind hole 51. Accordingly, the residue of the resin or the like is less likely to remain inside the blind hole 51, and the bonding between the metal portion 20 and the conductor 40 can be further improved.

As for the moving direction of the irradiation position of the second laser light L2, preferably, the irradiation position is first moved spirally or concentrically so as to surround the blind hole 51 on the first surface 10A of the insulating portion 10 apart from the blind hole 51, and the irradiation position is brought closer to the blind hole 51 while reducing the diameter of the rotation for each rotation. For example, after the n-th round of irradiation is performed along one concentric circle surrounding the blind hole 51 while moving the irradiation position from the outer peripheral side toward the inner peripheral side of the circle, the (n+1)-th round of irradiation is performed along the adjacent concentric circle closer to the blind hole 51. Furthermore, the (n+2)-th round of irradiation is performed along the adjacent concentric circle closer to the blind hole 51. The irradiation position can be moved by repeating this operation. In this way, the second laser light L2 is irradiated spirally or concentrically from the outer peripheral side of the blind hole 51 toward the inner side of the blind hole 51. That is, the stepped portion 55 is formed by irradiating the first surface 10A of the insulating portion 10 around the blind hole 51 with the second laser light L2, and thereafter the second laser light L2 is irradiated into the blind hole 51.

Preferably, the irradiation of the second laser light L2 is performed while continuously moving the irradiation position so as to form a spiral shape or a concentric shape from the outer peripheral side of the blind hole 51 toward the center of the bottom surface 51B defining the blind hole 51. As an example, an interval S2 between the recesses 60 arranged in a spiral shape or a concentric shape in the direction from the outer peripheral side of the blind hole 51 toward the center of the blind hole 51 on the bottom surface 51B defining the blind hole 51 can be set to a range from 5 μm to 50 m. The interval S2 between the recesses is the interval between adjacent spiral or concentric tracks on which the center of each shot of the second laser light L2 moves. The position at which the irradiation with the second laser light L2 is terminated may not coincide with the center of the bottom surface 51B defining the blind hole 51.

The blind hole 51 is preferably formed to have a maximum diameter in a range from 100 μm to 500 μm. When the blind hole 51 is small, it is difficult to inject the conductive paste 40A in a subsequent step. When the blind hole 51 is large, meanwhile, the metal portion 20 needs to be formed to be wide, and the arrangement of the wiring pattern of the metal portion 20 is limited. Therefore, the maximum diameter of the blind hole 51 is in a range from 50 μm to 800 μm, preferably in a range from 100 μm to 500 μm, and more preferably in a range from 200 μm to 300 μm.

In addition, in the forming S3 of a primary blind hole and the forming S4 of a blind hole, the blind hole 51 is formed such that the inside diameter D1 of the blind hole 51 increases from the second surface 10B toward the first surface 10A. That is, the blind hole 51 has a tapered shape tapered toward the bottom surface 51B.

In addition, in the forming S3 of a primary blind hole and the forming S4 of a blind hole, the plurality of blind holes 51 each having the surface of a portion of the continuous metal portion 20 on the insulating portion 10 side as the bottom surface 51B are formed in parallel. In the disposing S5 of a conductive paste to be described below, portions of the conductive paste 40A in contact with the corresponding bottom surfaces 51B defining the plurality of blind holes 51 formed in parallel are continued via a portion of the conductive paste 40A on the first surface 10A.

Here, as an example, two blind holes 51 are formed in parallel at positions facing one connection pad portion 22 formed by the continuous metal portion 20. The surface of the connection pad portion 22 on the insulating portion 10 side serves as the bottom surfaces 51B defining the two blind holes 51. In the disposing S5 of a conductive paste, a conductive paste 40A is disposed such that portions of the conductive paste 40A in contact with the corresponding bottom surfaces 51B defining the two blind holes 51 are continuous via a portion of the conductive paste 40A on the first surface 10A. The blind hole 51 can be formed at a position facing the metal portion 20 regardless of whether it is the connection pad portion 22.

### Disposing Conductive Paste

In the disposing S5 of a conductive paste, an uncured conductive paste 40A having fluidity is disposed in the blind hole 51 and on the first surface 10A of the insulating portion 10. The conductive paste 40A can be injected from a nozzle of a dispenser, can be provided by screen printing, or can be provided by a combination of nozzle injection and screen printing such as screen printing after injection from a nozzle, for example.

Here, as an example, the conductive paste 40A is disposed via an opening portion MA1 of a mask M1. In a plan view, the area in which the opening portion MA1 of the mask M1 and the opening portion of the blind hole 51 overlap each other is in a range from 40% to 70%, preferably in a range from 45% to 60%, and more preferably in a range from 50% to 55% of the area of the opening portion of the blind hole 51. The conductive paste 40A can be disposed by screen printing or metal mask printing by using the mask M1.

As illustrated in FIG. 6, the opening portion MA1 of the mask M1 overlaps a part of the blind hole 51 in a plan view. FIG. 6 is a schematic plan view of the substrate 30 as seen along a direction facing the first surface 10A, and as an example, the connection pad portion 22 of the metal portion 20 is formed on the second surface 10B, which is the surface opposite to the first surface 10A, to serve as the bottom surface 51B defining the blind hole 51. The conductive paste 40A is disposed by being injected into the blind hole 51 from a region P11 in which the opening portion MA1 and the blind hole 51 overlap each other. As an example, the opening portion of the blind hole 51 has a circular shape, and the region P11 has a shape obtained by removing a bow shape from the opening portion of the blind hole 51. The position and amount of the conductive paste 40A to be injected into the blind hole 51 can be adjusted by adjusting the shape and size of the region P11.

As illustrated in FIG. 4E, the bottom surface 51B immediately after the injection has a portion that does not face the conductive paste 40A. The conductive paste 40A spreads so as to be in close contact with the bottom surface 51B due to its fluidity. At this time, air facing the bottom surface 51B is pushed out by the conductive paste 40A to be discharged to the outside from the blind hole 51 as an air flow A3, for example.

The conductive paste 40A is preferably disposed so as to cover all the recesses 60 and the lateral walls 70 formed on the bottom surface 51B. The conductive paste 40A is disposed so as to fully fill at least the first recess 61 and the second recess 62.

A reducing agent can be contained in the conductive paste 40A. When the conductive paste 40A contains a reducing agent, it is possible to improve the quality of bonding between the conductor 40 formed from the conductive paste 40A and the metal portion 20.

### Forming Conductor

In the forming S6 of a conductor, the disposed conductive paste 40A is cured. The conductive paste 40A is cured by heat treatment, for example.

The conductor 40 located inside the blind hole 51 preferably faces the entire bottom surface 51B defining the blind hole 51. Accordingly, the electrical resistance in the connection between the metal portion 20 and the conductor 40 is reduced. In addition, since the conductor 40 is not in contact with air, oxidation of the metal portion 20 can be suppressed.

The volume of the conductor 40 located inside the blind hole 51 is 80% or more, preferably 90% or more, and more preferably 100% of the volume of the blind hole 51. As the volume of the conductor 40 located inside the blind hole 51 approaches 100% of the volume of the blind hole 51, the wire resistance of the conductor 40 inside the blind hole 51 can be reduced.

In the method S10 of manufacturing the wiring substrate configured as described above, a portion of the metal portion 20 being the bottom surface 51B defining the blind hole 51 is irradiated with the second laser light L2 such that the plurality of recesses 60 including the first recess 61 and the second recess 62 are formed and the first lateral wall 71 is formed between the first recess 61 and the second recess 62, which makes it possible to improve the bonding strength between the metal portion 20 and the conductor 40 in the blind hole 51 and to reduce the resistance value. The irradiation is performed such that the first top portion 71A of the first lateral wall 71 is located immediately above the bottom surface 61B defining the first recess 61 and the first lower end portion 71B is located closer to the second recess 62 than the first top portion 71A. This further improves the bonding strength between the metal portion 20 and the conductor 40.

In addition, the irradiation of the second laser light L2 is performed on a region including the blind hole 51 and larger than the blind hole 51 in a plan view, and the stepped portion 55 is formed by irradiating the first surface 10A of the insulating portion 10 around the blind hole 51 with the second laser light L2, and thereafter the second laser light L2 is irradiated into the blind hole 51. By performing irradiation while continuously moving the irradiation position so as to form a spiral shape or a concentric shape from the outer peripheral side of the blind hole 51 toward the center of the bottom surface 51B defining the blind hole 51, it is possible to enhance the accuracy of removal of the residue or the like and to efficiently clean the blind hole 51.

The second laser light L2 can be irradiated to a part of the region of the bottom surface 51B defining the blind hole 51. The removal of the anti-rust layer 21 in the region not irradiated with the second laser light L2 can be performed by containing a reducing agent in the conductive paste 40A in the disposing S5 of a conductive paste. The laser light irradiation for removing the anti-rust layer 21 can be performed separately from the formation of the recess 60, or the anti-rust layer 21 can be removed by grinding with a tool. The removal of the anti-rust layer 21 can be performed by any one of laser light irradiation, grinding with a tool, and addition of a reducing agent to the conductive paste, or can be performed by a combination of two or more thereof.

### Light-Emitting Device

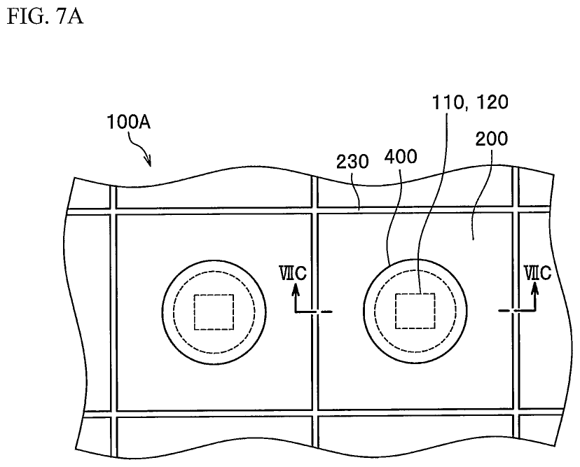

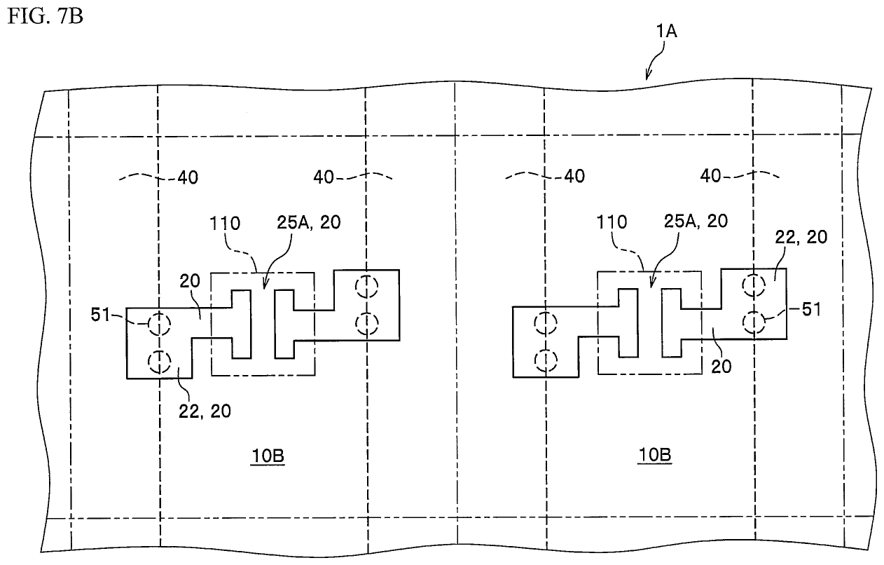

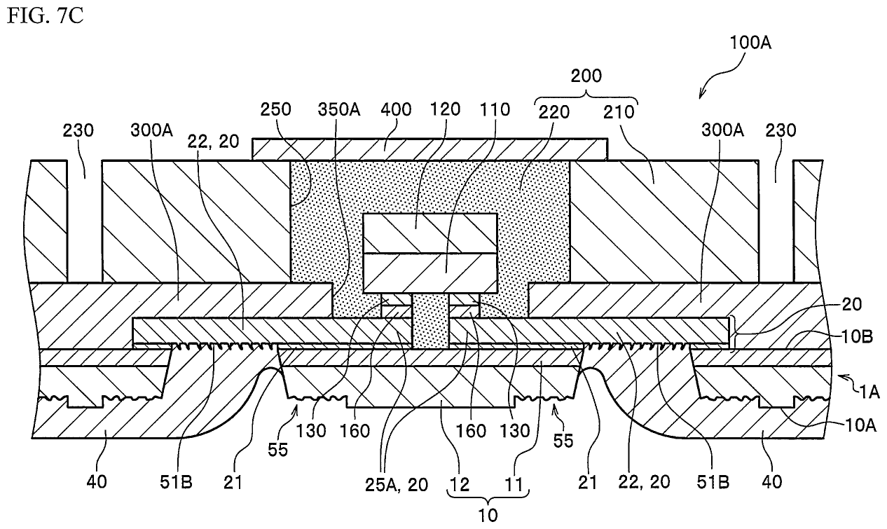

A light-emitting device 100A according to an embodiment will be described with reference to FIGS. 7A to 7C. FIG. 7A is a schematic plan view illustrating a part of the light-emitting device 100A. FIG. 7B is a schematic plan view illustrating a part of a wiring substrate 1A. FIG. 7C is a schematic cross-sectional view illustrating a part of the light-emitting device 100A. FIG. 7B illustrates the wiring substrate 1A in a part of the light-emitting device 100A illustrated in FIG. 7A.

The light-emitting device 100A is a device that can emit light by arranging light-emitting elements 110 on the wiring substrate 1. The light-emitting elements 110 can be aligned in the row direction and the column direction, for example, or can be aligned in any one of the row direction and the column direction. The number of light-emitting elements 110 can be set, as necessary. The number of light-emitting elements 110 can be one.

The wiring substrate configured as described above is used as the wiring substrate 1. Various patterns of wires can be formed on the wiring substrate 1, depending on the application. The wiring substrate 1 used in the light-emitting device 100A includes, for the light-emitting device 100A, an electrode and a wire on which the light-emitting element 110 is disposed and will be described as a wiring substrate 1A. The wiring substrate 1A includes an electrode 25A on the metal portion 20, and the light-emitting element 110 is disposed on the electrode 25A.

The light-emitting device 100A includes a wiring substrate 1A and a light-emitting element 110 disposed on the wiring substrate 1A, and the light-emitting element 110 is electrically connected to the metal portion 20. Here, the light-emitting device 100A further includes a light-transmissive member 120 disposed on the light extraction surface of the light-emitting element 110, a light-reflecting member 300A covering the metal portion 20, a light guide member 200 covering the light-emitting element 110, the light-transmissive member 120, and the light-reflecting member 300A, and a light adjustment member 400 disposed above the light-emitting element 110 and the light-transmissive member 120.

In the light-emitting device 100A, the light-emitting element 110 is disposed on the second surface 10B side of the insulating portion 10 of the wiring substrate 1A. The second surface 10B side of the insulating portion 10 on which the light-emitting element 110 is disposed will be described as the upper surface side of the wiring substrate 1A.

### Light-Emitting Element

The light-emitting element 110 is a member that includes a pair of element electrodes 130 and emits light when supplied with electric power.

The light-emitting element 110 includes a semiconductor layered body. In the present embodiment, the light-transmissive member 120 is disposed on an upper surface of the semiconductor layered body, and the pair of element electrodes 130 is provided on a lower surface of the semiconductor layered body. The semiconductor layered body can have any composition depending on the desired emission wavelength. For example, a nitride semiconductor (InₓAl_{y}Ga_{1-x-y}N, where 0≤x, 0≤y, x+y≤1) or GaP that can emit blue or green light, or GaAlAs or AlInGaP that can emit red light can be used. The size and shape of the light-emitting element 110 can be appropriately selected according to the purpose of use.

### Light-Transmissive Member

The light-transmissive member 120 is disposed on the light extraction surface of the light-emitting element 110. For example, the light-transmissive member 120 is made of a light-transmissive resin material, and an epoxy resin, a silicone resin, a resin in which an epoxy resin and a silicone resin are mixed, or the like can be used. The light-transmissive member 120 can contain a phosphor. For example, when the light-transmissive member 120 contains a phosphor that absorbs blue light from the light-emitting element 110 and emits yellow light, white light can be emitted from the light-emitting device 100A. Furthermore, the light-transmissive member 120 can contain a plurality of types of phosphors. For example, when the light-transmissive member 120 contains a phosphor that absorbs blue light from the light-emitting element 110 and emits green light and a phosphor that emits red light, white light can be emitted from the light-emitting device 100A.

Examples of the phosphor include an yttrium aluminum garnet-based phosphor (Y₃(Al,Ga)₅O₁₂:Ce, for example), a lutetium aluminum garnet-based phosphor (Lu₃(Al,Ga)₅O₁₂:Ce, for example), a terbium aluminum garnet-based phosphor (Tb₃(Al,Ga)₅O₁₂:Ce, for example), a β-SiAlON based phosphor ((Si,Al)₃(O,N)₄:Eu, for example), an α-SiAlON based phosphor (Mz(Si,Al)₁₂(O,N)₁₆, for example (where 0<z≤2, and M is Li, Mg, Ca, Y, and a lanthanide element excluding La and Ce)), a nitride phosphor such as a CASN-based phosphor (CaAlSiN₃:Eu, for example) or an SCASN-based phosphor ((Sr,Ca)AlSiN₃:Eu, for example), a fluoride phosphor such as a KSF-based phosphor (K₂SiF₆:Mn, for example), a KSAF-based phosphor (K₂(Si,Al)F₆:Mn, for example), or an MGF-based phosphor (3.5MgO·0.5MgF₂·GeO₂:Mn, for example), a quantum dot phosphor such as perovskite or chalcopyrite, and the like.

### Light-Reflecting Member

The light-reflecting member 300A is a sheet-like member having light reflectivity. The light-reflecting member 300A is disposed on the second surface 10B of the insulating portion 10 in the wiring substrate 1A and covers the metal portion 20. However, here, the light-reflecting member 300A has an opening portion 350A surrounding the light-emitting element 110 and the light-transmissive member 120, and the opening portion 350A surrounds the periphery of the light-emitting element 110 and the light-transmissive member 120 at a distance of about 50 μm to 100 μm in a plan view. Therefore, the light-reflecting member 300A covers the metal portion 20 except for a part located inside the opening portion 350A. The same applies to a method S100A of manufacturing a light-emitting device to be described below.

The light-reflecting member 300A preferably has a high reflectance and is preferably white in order to effectively use the light from the light-emitting element 110. The reflectance of the light-reflecting member 300A is preferably 90% or more, and more preferably 94% or more, for example, at the wavelength of the light emitted by the light-emitting element 110.

For the light-reflecting member 300A, a resin sheet including a large number of bubbles (for example, a foamed resin sheet), a resin sheet including a light diffusion material, or the like can be used. As a resin used for the light-reflecting member 300A, a thermoplastic resin such as an acrylic resin, a polycarbonate resin, a cyclic polyolefin resin, a polyethylene terephthalate resin, a polyethylene naphthalate resin, or a polyester resin, or a thermosetting resin such as an epoxy resin or a silicone resin can be used, for example. Examples of the light diffusion material include well-known materials such as titanium oxide, silicon oxide, aluminum oxide, and zinc oxide, and glass.

### Light Guide Member

The light guide member 200 is a member that transmits and conducts light from the light-emitting element 110 and the light-transmissive member 120. The light guide member 200 includes a first light guide member 210 that covers the light-reflecting member 300A and a second light guide member 220 that covers the light-emitting element 110 and the light-transmissive member 120. The first light guide member 210 is a plate-like or sheet-like member having translucency. However, here, the first light guide member 210 has an opening portion 250 surrounding the light-emitting element 110 and the light-transmissive member 120. The opening portion 250 surrounds the periphery of the light-emitting element 110 and the light-transmissive member 120 at a distance of about 100 μm to 200 μm in a plan view and has a size that includes the opening portion 350A of the light-reflecting member 300A at a position facing the opening portion 350A. Therefore, the first light guide member 210 covers the light-reflecting member 300A except for a part located inside the opening portion 250. The second light guide member 220 is disposed so as to fill the opening portion 250 of the first light guide member 210 and cover from the opening portion 350A to the light-emitting element 110 and the light-transmissive member 120.

Examples of the material that can be used for the first light guide member 210 include a thermoplastic resin such as acrylic, polycarbonate, cyclic polyolefin, polyethylene terephthalate, or polyester, and a material having translucency such as glass. In particular, polycarbonate that has high transparency and is inexpensive is preferably used. The material of the second light guide member 220 is not limited as long as the material is a transparent resin. However, a thermosetting resin such as an epoxy resin, a silicone resin, or an acrylic resin is preferably used.

The light guide member 200 is partitioned for each light-emitting element 110 by partition grooves 230. The partition grooves 230 are provided to reduce light transmitted through the light guide member 200 from the adjacent light-emitting elements 110 and light-transmissive members 120. The partition grooves 230 can be a gap that splits the light guide member 200, or the light guide member 200 can be partially continuous. In addition, a member having light reflectivity can be disposed in the partition grooves 230. The member having light reflectivity can be formed by containing a light diffusion material in a resin which is the material of the light guide member 200. As the light diffusion material, titanium oxide, silicon oxide, aluminum oxide, or the like can be used, for example.

### Light Adjustment Member

The light-emitting device 100A can include light adjustment members 400. The light adjustment member 400 is a film-like or plate-like member that reflects a part of light from the light-emitting element 110 toward the light-reflecting member 300A. The light adjustment member 400 is disposed on the surface of the light guide member 200 at a position overlapping the light-emitting element 110 in a plan view.

The transmittance of the light adjustment member 400 is preferably in a range from 20% to 60%, and more preferably in a range from 30% to 40%, for example, with respect to the light from the light-emitting element 110 and the light-transmissive member 120. A material used for the light adjustment member 400 can be a resin material containing a light diffusion material, or a metal material, for example. The resin material can be a silicone resin, an epoxy resin, or a resin obtained by mixing these resins, for example. Examples of the light diffusion material include well-known materials such as titanium oxide, silicon oxide, aluminum oxide, and zinc oxide, and glass. The light adjustment member 400 can have any size as long as the light adjustment member 400 covers the light-emitting element 110 and the light-transmissive member 120 at a position facing the light-emitting element 110 and the light-transmissive member 120 in a plan view and can have a rectangular shape or the like although it has a circular shape in FIG. 7A.

### Method for Manufacturing Light-Emitting Device

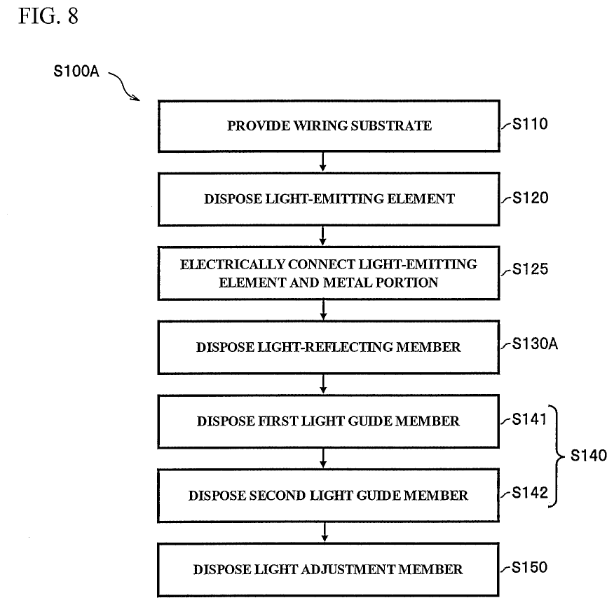

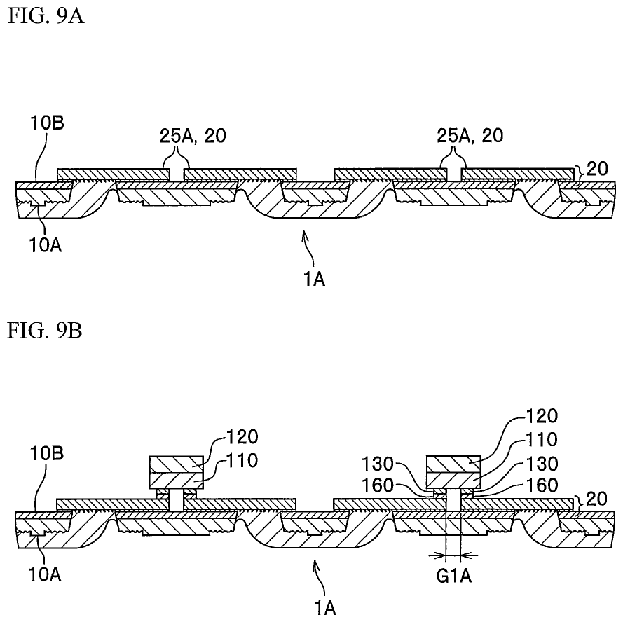

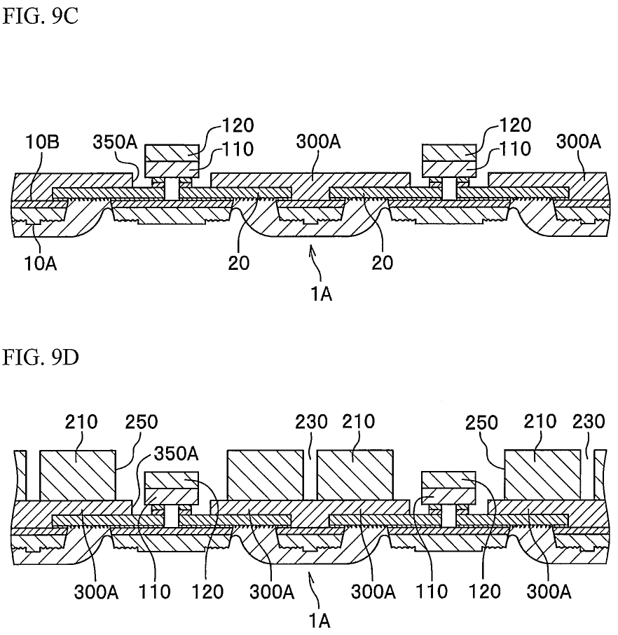

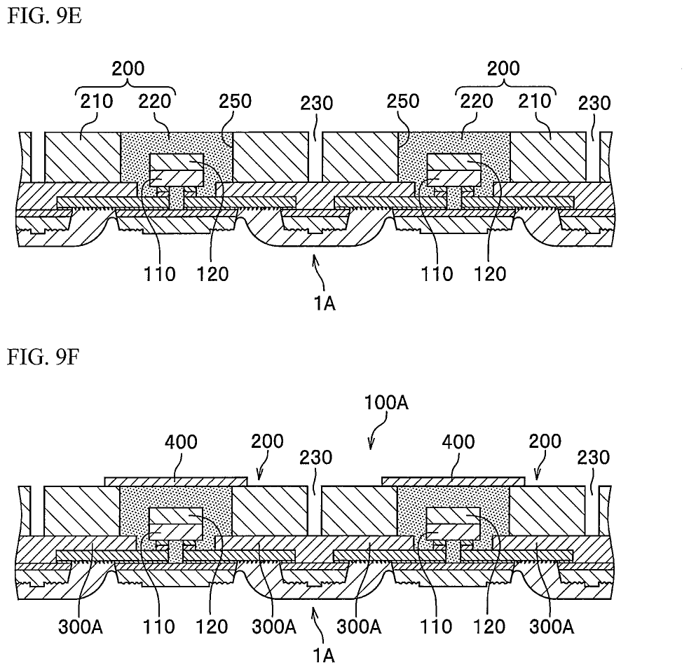

A method S100A of manufacturing a light-emitting device will be described with reference to FIGS. 8 and 9A to 9F. FIG. 8 is a flowchart of a method S100A of manufacturing a light-emitting device. FIG. 9A is a schematic cross-sectional view illustrating a provided wiring substrate 1A. FIG. 9B is a schematic cross-sectional view illustrating a state in which light-emitting elements 110 have been disposed. FIG. 9C is a schematic cross-sectional view illustrating a state in which a light-reflecting member 300A has been disposed. FIG. 9D is a schematic cross-sectional view illustrating a state in which a first light guide member 210 has been disposed. FIG. 9E is a schematic cross-sectional view illustrating a state in which a second light guide members 220 have been disposed. FIG. 9F is a schematic cross-sectional view illustrating a state in which light adjustment members 400 have been disposed.

The method S100A of manufacturing the light-emitting device includes providing S110 a wiring substrate by the method S10 of manufacturing the wiring substrate; disposing S120 a light-emitting element 110 on the wiring substrate 1A; and electrically connecting S125 the light-emitting element 110 to the metal portion 20. Here, the method further includes disposing S130A a light-reflecting member 300A so as to cover the metal portion 20; disposing S141 a first light guide member 210 so as to cover the light-reflecting member 300A; disposing S142 a second light guide member 220; and disposing S150 a light adjustment member 400.

### Providing Wiring Substrate

In the providing S110 of the wiring substrate, a wiring substrate 1A is provided by the method S10 of manufacturing the wiring substrate. In FIG. 9A, the second surface 10B of the insulating portion 10 on which the metal portion 20 is disposed is the upper surface in the drawing. The gap between the electrodes 25A can be adjusted according to the light-emitting elements 110. Here, a gap G1A is set such that the electrodes 25A face the pair of element electrodes 130.

### Disposing Light-Emitting Elements

In the disposing S120 of the light-emitting element, a light-emitting element 110 is disposed on the wiring substrate 1A. In the method S100A of manufacturing the light-emitting device, the element electrodes 130 of the light-emitting element 110 are disposed so as to face the electrodes 25A of the metal portion 20 on the wiring substrate 1A.

### Electrically Connecting Light-Emitting Element to Metal Portion

In the electrically connecting S125 of the light-emitting element to the metal portion, the element electrodes 130 of the light-emitting element 110 are electrically connected to the metal portion 20. The pair of element electrodes 130 is bonded to the corresponding electrodes 25A via conductive adhesive members 160. As the conductive adhesive member 160, for example, a bump made of gold, silver, copper, or the like, a conductive paste that is a mixture of a resin binder and powder of a metal such as gold, silver, copper, platinum, or aluminum, a tin-silver-copper (SAC) based solder, or a tin-bismuth (SnBi) based solder can be used. Here, the light-emitting element 110 is disposed by reflow soldering. The conductive adhesive members 160 are disposed between the pair of element electrodes 130 and the electrodes 25A.

### Disposing Light-Reflecting Member

In the disposing S130A of the light-reflecting member, a light-reflecting member 300A is disposed so as to cover the metal portion 20. The light-reflecting member 300A has opening portions 350A each formed so as to surround the light-emitting element 110 and is disposed such that the light-emitting elements 110 are located in the corresponding opening portions 350A. An adhesive sheet having both surfaces as adhesive surfaces or tacky surfaces is attached to the upper surface and the lower surface of the light-reflecting member 300A. The adhesive sheet is made of urethane, acrylic resin, or the like and has a thickness of about 10 μm to 75 μm. Furthermore, it is desirable to improve the reflectance of the adhesive sheet by adding titanium oxide, barium sulfate, or the like. A white bonding sheet can be used as the adhesive or tacky sheet and can be stacked or sandwiched with a white polyethylene terephthalate sheet to further increase the reflectance. The light-reflecting member 300A can be disposed by applying an adhesive without using an adhesive sheet.

### Disposing First Light Guide Member

In the disposing S141 of the first light guide member, a first light guide member 210 is disposed so as to cover the light-reflecting member 300A. The first light guide member 210 is a plate-like or sheet-like member in which opening portions 250 are formed so as to surround the light-emitting elements 110 and the light-transmissive members 120 and is disposed such that the light-emitting elements 110 and the light-transmissive members 120 are located in the corresponding opening portions 250. The first light guide member 210 is bonded to the light-reflecting member 300A by being pressed toward the wiring substrate 1A while being heated after being aligned. The first light guide member 210 is partitioned by the partition grooves 230. A member having light reflectivity can be disposed in the partition groove 230.

### Disposing Second Light Guide Member

In the disposing S142 of the second light guide member, a second light guide member 220 is disposed so as to cover the light-emitting element 110 and the light-transmissive member 120. The second light guide member 220 can be disposed so as to cover the light-emitting element 110 and the light-transmissive member 120 by injecting a liquid or paste resin from the opening portion 250 of the first light guide member 210 and curing the resin. The material of the second light guide member 220 can be the same as or different from that of the first light guide member 210. In S142, the same material as that of the first light guide member 210 is injected from the opening portion 250 in an uncured state and cured.

The disposing S141 of the first light guide member and the disposing S142 of the second light guide member are combined into disposing S140 of a light guide member.

### Disposing Light Adjustment Member

In the disposing S150 of the light adjustment member, a light adjustment member 400 is disposed on the surface of the light guide member 200 at a position overlapping the light-emitting element 110 and the light-transmissive member 120 in a plan view. The light adjustment member 400 can be formed by applying a resin as the material on the light guide member 200 and curing the resin or can be formed by disposing a film-like or plate-like member. Here, as an example, a silicone resin containing titanium oxide is disposed at a position facing the light-emitting element 110 and the light-transmissive member 120 on the surface of the light guide member 200.

1. A wiring substrate comprising:
a substrate comprising an insulating portion and a metal portion, the insulating portion having a first surface and a second surface opposite to the first surface, the insulating portion comprising a through hole penetrating and connecting the first surface and the second surface, the metal portion facing the second surface of the insulating portion, the metal portion closing the through hole to form a blind hole; and
a conductor disposed in the blind hole,
wherein a portion of the metal portion being a bottom surface defining the blind hole comprises at least a first recess, a second recess, and a first lateral wall located between the first recess and the second recess, and
wherein, in a cross-sectional view taken along a thickness direction of a portion of the metal portion located in the blind hole, the first lateral wall comprises a first lower end portion located in the first recess, a second lower end portion located in the second recess, and a first top portion located between the first lower end portion and the second lower end portion, the first top portion is located immediately above a bottom surface defining the first recess, and the first lower end portion is located closer to the second recess than the first top portion.

2. The wiring substrate according to claim 1,
wherein the bottom surface defining the blind hole has a circular shape in a plan view,
wherein the portion of the metal portion being the bottom surface defining the blind hole comprises a third recess adjacent to the second recess and opposite to the first recess, and comprises a second lateral wall located between the second recess and the third recess, and
wherein the first recess, the second recess, and the third recess are disposed in an arc shape along an outer periphery of the bottom surface defining the blind hole having the circular shape.

3. The wiring substrate according to claim 1, wherein the portion of the metal portion being the bottom surface defining the blind hole comprises a plurality of recesses comprising the first recess and the second recess, and the plurality of recesses are disposed in a spiral shape.

4. The wiring substrate according to claim 1, wherein a height from the bottom surface defining the first recess to the first top portion is in a range from 0.5 μm to 10 μm.

5. The wiring substrate according to claim 1,
wherein the portion of the metal portion being the bottom surface defining the blind hole comprises a plurality of recesses comprising the first recess and the second recess, and lateral walls each located between adjacent recesses of the plurality of recesses, the lateral walls comprising the first lateral wall, and
wherein a mode value of an area of a bottom surface defining each of the plurality of recesses not covered with the lateral walls in a plan view is in a range from 10 μm² to 50 μm².

6. The wiring substrate according to claim 1, wherein the first surface of the insulating portion comprises a stepped portion where a part of a surface has been removed, the stepped portion surrounding the blind hole.

7. The wiring substrate according to claim 6, wherein a height of a step of the stepped portion is in a range from 0.1 μm to 10 μm.

8. The wiring substrate according to claim 6, wherein a width of the stepped portion is in a range from 1 μm to 400 μm.

9. The wiring substrate according to claim 1, wherein an inside diameter of the blind hole increases from the second surface toward the first surface.

10. The wiring substrate according to claim 1, wherein a maximum diameter of the blind hole is in a range from 100 μm to 500 μm.

11. The wiring substrate according to claim 1,
wherein the metal portion is a copper plate, and comprises an anti-rust layer on a surface facing the second surface of the insulating portion, and
wherein the portion of the metal portion being the bottom surface defining the blind hole comprises a region where the anti-rust layer has been removed.

12. A light-emitting device comprising:
the wiring substrate according to claim 1; and
a light-emitting element disposed on the wiring substrate,
wherein the light-emitting element is electrically connected to the metal portion.

13. A method of manufacturing a wiring substrate, the method comprising:
providing a substrate comprising an insulating portion and a metal portion, the insulating portion having a first surface and a second surface opposite to the first surface, the metal portion facing the second surface of the insulating portion;
forming a primary blind hole by irradiating a first surface of the insulating portion with first laser light and removing at least a part of the insulating portion;
forming a blind hole having a portion of the metal portion as a bottom surface by irradiating a bottom surface defining the primary blind hole with second laser light having a shorter wavelength than the first laser light;
disposing a conductive paste in the blind hole; and
forming a conductor by curing the conductive paste,
wherein, in the forming the blind hole, the second laser light is irradiated in such a manner that, in the portion of the metal portion being the bottom surface defining the blind hole, a plurality of recesses comprising at least a first recess and a second recess are formed, and a first lateral wall is formed between the first recess and the second recess.

14. The method of manufacturing the wiring substrate according to claim 13, wherein, in the forming the blind hole, the second laser light is irradiated in such a manner that, in a cross-sectional view taken along a thickness direction of a portion of the metal portion located in the blind hole, the first lateral wall comprises a first lower end portion located in the first recess, a second lower end portion located in the second recess, and a first top portion located between the first lower end portion and the second lower end portion, the first top portion is located immediately above a bottom surface defining the first recess, and the first lower end portion is located closer to the second recess than the first top portion.

15. The method of manufacturing the wiring substrate according to claim 13,
wherein, in the forming the blind hole and when the portion of the metal portion being the bottom surface defining the blind hole is irradiated with the second laser light, the first recess and the first lateral wall are formed by irradiating the portion of the metal portion with first emission light from the second laser light directly or via the insulating portion, and
wherein the second recess is formed and the first lateral wall is deformed in such a manner that the first lateral wall is inclined toward the first recess by irradiating the portion of the metal portion with second emission light from the second laser light directly, or via the insulating portion in such a manner that the second emission light partially overlaps the first lateral wall.

16. The method of manufacturing the wiring substrate according to claim 13, wherein, in the forming the blind hole, the second laser light is irradiated in a spiral shape or a concentric shape from an outer peripheral side of the blind hole toward an inner side of the blind hole.

17. The method of manufacturing the wiring substrate according to claim 13, wherein, in the forming the blind hole, the second laser light is irradiated while continuously moving an irradiation position in such a manner that the irradiation position draws a spiral shape or a concentric shape from an outer peripheral side of the blind hole toward a center of the bottom surface defining the blind hole.

18. The method of manufacturing the wiring substrate according to claim 13, wherein, in the forming the blind hole, irradiation of the second laser light is performed on a region including the blind hole and larger than the blind hole in a plan view.

19. The method of manufacturing the wiring substrate according to claim 13, wherein, in the forming the blind hole, a stepped portion is formed by irradiating the first surface of a portion of the insulating portion around the blind hole with the second laser light.

20. The method of manufacturing the wiring substrate according to claim 13, wherein, in the forming the blind hole, the second laser light is irradiated into the blind hole after a stepped portion is formed by irradiating the first surface of a portion of the insulating portion around the blind hole with the second laser light.

21. The method of manufacturing the wiring substrate according to claim 16, wherein, in the forming the blind hole, an interval between the plurality of recesses arranged in the spiral shape or the concentric shape in a direction from the outer peripheral side of the blind hole toward a center of the blind hole on the bottom surface defining the blind hole is in a range from 5 μm to 50 μm.

22. The method of manufacturing the wiring substrate according to claim 13, wherein, in the forming the blind hole, a beam diameter of the second laser light on the bottom surface defining the blind hole is in a range from 10 μm to 50 μm.

23. The method of manufacturing the wiring substrate according to claim 13, wherein, in the forming the blind hole, the second laser light is pulsed laser light, and a single recess of the plurality of recesses is formed by a single shot of the pulsed laser light.

24. The method of manufacturing the wiring substrate according to claim 23, wherein, in the forming the blind hole, an interval between irradiation positions of a plurality of the consecutive single shots on the bottom surface defining the blind hole is in a range from 5 μm to 50 μm.

25. The method of manufacturing the wiring substrate according to claim 13,
wherein, in the forming the primary blind hole, a wavelength of the first laser light is in a range from 9.3 μm to 10.6 μm, and
wherein, in the forming the blind hole, a wavelength of the second laser light is in a range from 355 nm to 532 nm.

26. The method of manufacturing the wiring substrate according to claim 13, wherein, in the providing the substrate, an anti-rust layer is provided on a surface of the metal portion facing the second surface of the insulating portion.

27. The method of manufacturing the wiring substrate according to claim 26, wherein, in the forming the blind hole, the anti-rust layer provided on a surface of the portion of the metal portion being the bottom surface defining the blind hole is removed by irradiation with the second laser light.

28. The method of manufacturing the wiring substrate according to claim 13, wherein, in the disposing the conductive paste, the conductive paste is disposed in such a manner that the conductive paste fully fills at least the first recess and the second recess.

29. The method of manufacturing the wiring substrate according to claim 13, wherein, in the disposing the conductive paste, the conductive paste contains a reducing agent.

30. The method of manufacturing the wiring substrate according to claim 13, wherein, in the forming the primary blind hole and the forming the blind hole, the blind hole is formed in such a manner that an inside diameter of the blind hole increases from the second surface toward the first surface.

31. The method of manufacturing the wiring substrate according to claim 13, wherein, in the forming the blind hole, the blind hole is formed in such a manner that a maximum diameter of the blind hole is in a range from 100 μm to 500 μm.

32. A method of manufacturing a light-emitting device, the method comprising:
providing a wiring substrate by the method of manufacturing the wiring substrate according to claim 13;
disposing a light-emitting element on the wiring substrate; and
electrically connecting the light-emitting element and the metal portion.
